(19) United States
(12) Patent Application Publication
(10) Pub. No.: US 2007/0046354 A1
(43) Pub. Date: Mar. 1, 2007

(54) Delay adjustment circuit and synchronous semiconductor device having the delay adjustment circuit

(75) Inventors: Koji Kuroki, Tokyo (JP); Hiroki Fujisawa, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 11/511,352

(22) Filed: Aug. 29, 2006

(30) Foreign Application Priority Data
Aug. 31, 2005 (JP) 2005-251116

(51) Int. Cl. H03H 11/26

(52) U.S. Cl. 327/261

(57) ABSTRACT

Disclosed is a delay adjustment circuit including a first set of transistors, which are connected between a PMOS transistor forming an inverter and a power supply in parallel and have gates supplied with control signals, respectively, a second set of transistors which are connected between an NMOS transistor forming the inverter, and the ground GND, in parallel and have gates supplied with control signals, respectively, and another inverter receiving an output of the inverter as an input. At least one of the transistors of the first set of transistors and at least one of the transistors of the second set of transistors are set in an on-state.

### FIELD OF THE INVENTION

This invention relates to a semiconductor device and, more particularly, to a synchronous semiconductor device having a delay adjustment circuit.

### BACKGROUND OF THE INVENTION

Clock synchronous semiconductor devices are requested to have high operation frequency in order to meet market needs. The specifications for a setup time and a hold time are becoming more and more stringent as the operation frequency becomes higher. A delay adjustment circuit is usually provided as a means for adjusting the setup time and the hold time. It is noted that, for reducing the TAT (turnaround time) at the development cycle, control is exercised so that the amount of delay is variably adjustable during e.g. the test mode. Meanwhile, the setup time is the time relative to a clock sampling edge during which the data input to a latch or flip-flop must remain stable in order for the data to be latched correctly. The hold time is the time from the clock sampling edge during which the data input to a latch or flip-flop must remain unchanged in order for the data to be latched correctly.

In the conventional delay adjustment circuit, there is a drawback that the propagation delay time (tPD) from the transition of an input signal of the delay adjustment circuit to the transition of an output signal of the delay adjustment circuit, is long, or that the width of adjustment is narrow.

FIG. 4 is a diagram showing an example of the typical configuration of the conventional delay adjustment circuit. In FIG. 4, the configuration of a latch circuit for an address signal (ADD) of a clock synchronous semiconductor memory, is shown only by way of illustration. Referring to FIG. 4, complementary clock signals CK and CKB are differentially received by an input circuit 104 which supplies a single-ended output signal to an internal clock generating circuit 105. The internal clock generating circuit 105 generates an internal clock signal and supplies the internal clock signal to a clock terminal of a latch circuit 103. An address and a reference voltage VREF are differentially received by an input circuit 101 which outputs a single-ended output signal. The output of the input circuit 101 and the output of the input circuit 101 delayed by a delay circuit 106 are supplied as inputs to the selector circuit 107 which then selects one of them. An output of the selector circuit 107 and the output of the selector circuit 107 delayed by a delay circuit 108 are supplied as inputs to a selector circuit 109 which then selects of them. An output of the selector circuit 109 is supplied to a data input terminal of the latch circuit 103. The delay circuits 106, and 108 and the selector circuits 107 and 109 compose the delay adjustment circuit. The selection of the input signal by the selector circuits 107 and 109 is controlled by e.g. a test mode to provide for a variable amount of delay.

With the configuration of FIG. 4, the following problems arise.

The first problem is that the width of adjustment for the delay of the delay adjustment circuit is excessively large, that is, the difficulty is met in fine adjustment. The reason is that the delay adjustment circuit is made up of the delay circuits and the selector circuits, resulting in larger numbers of the logic stages. With the configuration of FIG. 4, the minimum adjustment width is e.g. hundreds of picoseconds (ps), such that it is difficult to make the adjustment within a width of tens of picoseconds (ps).

The second problem is the longer propagation delay (tPD) which is the time from transition of a signal in a first input stage to a transition of the signal the latch circuit 103 through the delay adjustment circuit. The reason is that the delay adjustment circuit is made up of a plural number of cascade-connected circuit units, each of which is composed of the delay circuit and the selector circuit, accounting for an increased number of logic stages, as mentioned above.

FIG. 5 is a diagram showing the configuration disclosed in Patent Document 1 (JP Patent Kokai Publication No. JP-A-6-61808). Referring to FIG. 5, a P-channel MOS transistor 3 and an N-channel MOS transistor 6 of an inverter 1 operate as a switch on/off controlled by an input signal from an input terminal 1. A P-channel MOS transistor 4 and an N-channel MOS transistor 7 operate as voltage controlled variable resistors, whilst a P-channel MOS transistor 5 and an N-channel MOS transistor 8 operate as constant resistance units. When the input signal is changed from LOW to HIGH, the on-resistance of the inverter 1 is varied, based on the control voltage applied to a control terminal B, in such a manner as to control the amount of delay of rising edge. When the input signal is changed from HIGH to LOW, the on-resistance of the inverter 1 is varied, based on the control voltage applied to a control terminal A, in such a manner as to control the amount of delay of falling edge. A P-channel MOS capacitor 9 is connected between the input terminal I and the control terminal A, whilst an N-channel MOS capacitor 10 is connected between the input terminal I and the control terminal B. To an output of the inverter 1 is connected a capacitor C made up by gate capacitances of a P-channel MOS transistor 11 and an N-channel MOS transistor 12 and an output capacitance of the inverter 1.

[Patent Document 1]

JP Patent Kokai Publication No. JP-A-6-61808

### SUMMARY OF THE DISCLOSURE

An illustrative configuration in which, in the configuration of FIG. 5, the voltage controlled variable resistance unit of the P-channel MOS transistor 4 and the N-channel MOS transistor 7 is adapted to be controlled by e.g. the test mode, in order to carry out delay adjustment, will now be described as a comparative example of the present invention. FIG. 6 is a diagram showing the configuration of the comparative example. It should be noted that the present comparative example has not been disclosed in Patent Document 1, that is, the following shows the results of the study and analysis conducted by the present inventors.

In the circuit shown in FIG. 6, the P-channel transistor 4 in FIG. 5 is replaced by plural P-channel MOS transistors 4-1, 4-2 and 4-3, connected in parallel with one another, whilst the N-channel transistor 7 in FIG. 5 is replaced by plural N-channel MOS transistors 7-1, 7-2 and 7-3, connected in parallel with one another. The gates of the P-channel MOS transistors 4-1, 4-2 and 4-3 are supplied with signals A, C and D, respectively, whilst the gates of the N-channel MOS transistors 7-1, 7-2 and 7-3 are supplied with signals B, E and F, respectively. The on-resistances of the transistors are variably controlled by varying the bias voltages of the gates of the transistors.

The configuration of FIG. 6 operates at a high speed because there is no selector circuit such as one shown in FIG. 4. However, the propagation delay time (tPD) from the transition of an input I to the transition of an output O of the delay adjustment circuit is longer. This slow propagation is ascribable to the on-resistance and to the junction capacitances of the transistors 4-1, 4-2, 4-3, 7-1, 7-2 and 7-3 of the voltage controlled variable resistance units.

If, in the configuration shown in FIG. 6, the propagation delay time tPD is to be shorter, the following (I) or (II) may readily be adopted as measures to be taken.

(I) The channel widths W of the transistors 11 and 12 of the inverter 2 are reduced to suppress the gate capacitance, that is, to decrease the total capacitance.

(II) The channel widths W of the transistors 4-1, 4-2, 4-3, 7-1, 7-2 and 7-3 of the inverter 1 are increased, that is, the on-resistances of these transistors are decreased.

In the measures (1), it is the junction capacitances of the P-channel MOS transistors 4-1, 4-2 and 4-3 and the N-channel MOS transistors 7-1, 7-2 and 7-3 that is dominant, so that it may hardly be expected to make the propagation delay time tPD shorter. On the other hand, if the channel widths W of the transistors 11, 12 of the inverter 2 are decreased, the driving capability is lowered, such that it is only near-distance driving that may be feasible. Thus, if the circuit of FIG. 6 is applied to a long-distance driving, it becomes necessary to add e.g. a buffer on a succeeding stage of the inverter 2. The result is the increased number of logic stages and a further increase in the propagation delay time tPD.

On the other hand, if, in (II), the channel width W of the transistor of the inverter 1 is increased, the on-resistance value is decreased, however, the total output capacitance of the inverter 1 is increased, such that it is not possible to drastically reduce the propagation delay time tPD.

FIG. 7 shows the results of simulation of the circuit of FIG. 6. Meanwhile, FIG. 7 shows the results of circuit simulation (transient analysis) carried out for analysis of the circuit of FIG. 6.

In FIG. 7, I (input signal waveform) corresponds to a voltage waveform of the input signal I of FIG. 6, whilst output signal waveforms OUT1, OUT2 of FIG. 7 correspond to the voltage waveform of the output signal O of FIG. 6. The output signal waveform OUT2 is a signal waveform at the output terminal O in case the channel width W of the inverter 2 of FIG. 6 is doubled from the channel width of the inverter 2 which gives the output signal waveform OUT1 as a reference.

The propagation delay time from the rise of I to the rise of OUT2 is slightly shorter than that from the rise of I to the rise of OUT1. In case the value of W of the inverter 1 is doubled, the propagation delay time tPD may be shorter by a time which is on the order of 10 picoseconds (ps), such that no remarkable effect can be expected.

Accordingly, it is an object of the present invention to provide a delay adjustment circuit in which the propagation delay time is made shorter and fine adjustment of the delay time is possible.

A semiconductor device in accordance with one aspect of the present invention is a delay adjustment circuit in which the amount of delay of an input signal supplied to an input terminal is adjusted and the input signal thus adjusted for delay is output at an output terminal. The delay adjustment circuit includes: a buffer circuit having an input end connected to said input terminal; and at least one variable resistance device provided on a power supply path between said buffer circuit and a high potential power supply, and/or, at least one variable resistance device provided on a power supply path between said buffer circuit and a low potential power supply; wherein each resistance of said variable resistance devices is varied by a control signal received to adjust said amount of delay.

According to the present invention, in measuring the setup time and the hold time of a latch circuit, arranged on a succeeding stage of the delay adjustment circuit and supplied with an output signal of the delay adjustment circuit as input, fine adjustment of the amount of delay is made possible by the aforementioned control signals.

According to the present invention, as the variable resistance device, there is provided at least one of a first set of transistors arranged on a power supply path between the buffer circuit and a high potential power supply, and a second set of transistors arranged on a power supply path between the buffer circuit and a low potential power supply. There are supplied control signals to control terminals of the transistors of the first set of transistors, whilst there are also supplied other control signals to control terminals of the transistors of the second set of transistors.

According to the present invention, the buffer circuit is an inverter receiving an input signal from an input end and outputting an inverted signal at an output end.

A delay adjustment circuit according to the present invention includes: a first inverter circuit having an input end connected to said input terminal and having an output end for outputting a signal obtained on inverting said input signal supplied to said input end; a first set of transistors arranged in parallel with one another between a high potential side of said first inverter and a high potential power supply and having control terminals supplied with control signals, respectively; and a second set of transistors arranged in parallel with one another between a low potential side of said first inverter and a low potential power supply and having control terminals supplied with control signals, respectively; at least one of the first set of transistors being set in an on-state and at least one of the second set of transistors being set in an on-state.

According to the present invention, there is provided a second inverter circuit adapted for receiving an output signal of the first inverter circuit.

According to the present invention, the inverter is a CMOS inverter made up of a P-channel MOS transistor and an N-channel MOS transistor having gates connected in common to form an input end and having drains connected in common to form an output end. The first set of transistors is formed by a plurality of P-channel MOS transistors which have sources connected in common to the high potential power supply, have drains connected in common to the sources of P-channel MOS transistors of the CMOS inverter and have gates supplied with the control signals. The second set of transistors is formed by a plurality of N-channel MOS transistors which have sources connected in common to the low potential power supply, have drains connected in common to the sources of N-channel MOS transistors of the CMOS inverter and have gates supplied with the control signals.

The meritorious effects of the present invention are summarized as follows.

According to the present invention, a set(s) of variable resistance devices are provided between the high potential power supply and the inverter and/or between the low potential power supply and the inverter, and the driving capability of the inverter is varied by controlling the variable resistance devices. According to the present invention, fine adjustment of the setup time and the hold time of the latch circuit provided in a succeeding stage is made possible as the propagation delay time is suppressed from increasing.

Still other features and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWINGS

FIG. 1 is a block diagram showing the constitution of an embodiment of the present invention in its entirety.

FIG. 2 is a circuit diagram showing the constitution of the embodiment of the present invention.

FIG. 3 is a graph showing the results of simulation for illustrating the operation of the embodiment of the present invention.

FIG. 4 is a block diagram showing an illustrative configuration of a circuit which is in need of delay adjustment.

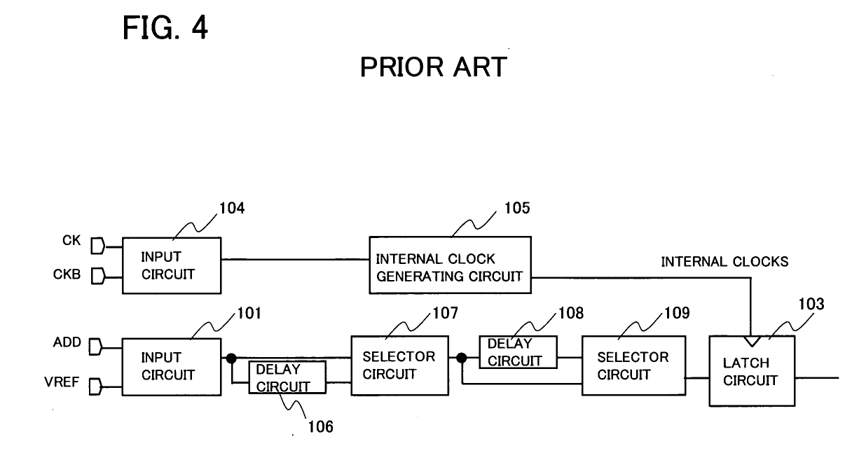

FIG. 5 is a circuit diagram showing the constitution of Patent Document 1.

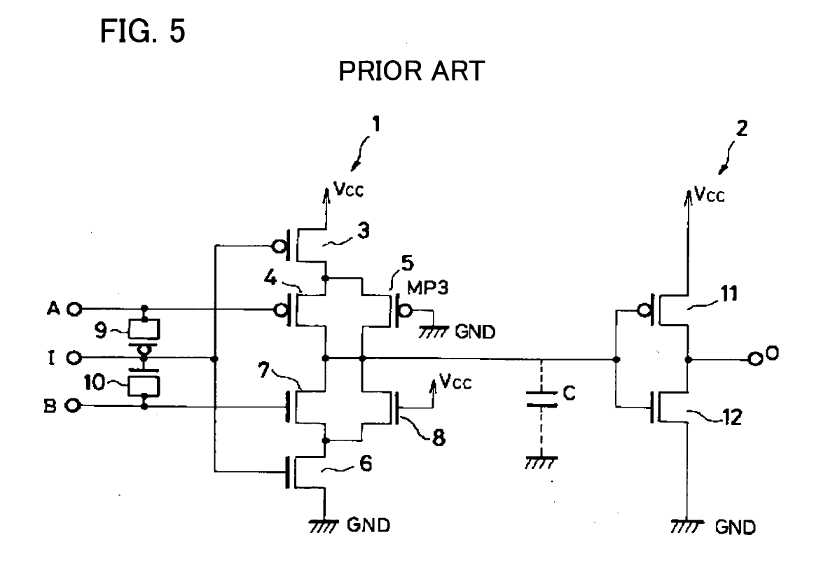

FIG. 6 is a circuit diagram showing the constitution of a comparative example.

FIG. 7 is a graph showing the results of simulation of the comparative example shown in FIG. 6.

### PREFERRED EMBODIMENTS OF THE INVENTION

A preferred embodiment of the present invention will now be described with reference to the accompanying drawings. The delay adjustment circuit of the present invention includes one or more variable resistance devices on a power supply path between an inverter receiving a signal supplied to an input terminal of the delay adjustment circuit and a high potential power supply and/or on a power supply path between the inverter and a low potential power supply. The resistances of the variable resistance devices are varied by control signals to vary the amount of delay. The embodiment of the present invention will now be described in detail. Meanwhile, the following description is directed to delay adjustment in a circuit which latches an address signal of a synchronous semiconductor memory. However, the present invention is not limited to the circuit of latching the address signal, or to a synchronous semiconductor memory, as a matter of course.

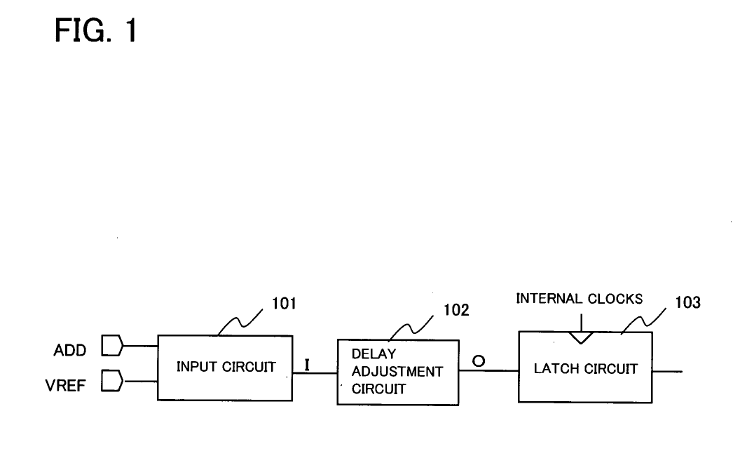

FIG. 1 shows the configuration of a first embodiment of the present invention. The present embodiment includes an input circuit (differential receiver) 101, adapted for receiving an address signal from an address terminal ADD, and a reference voltage VREF, a delay adjustment circuit 102 and a latch circuit 103. This latch circuit 103 samples an output of the delay adjustment circuit 102 with an internal clock signal from an internal clock generating circuit, not shown.

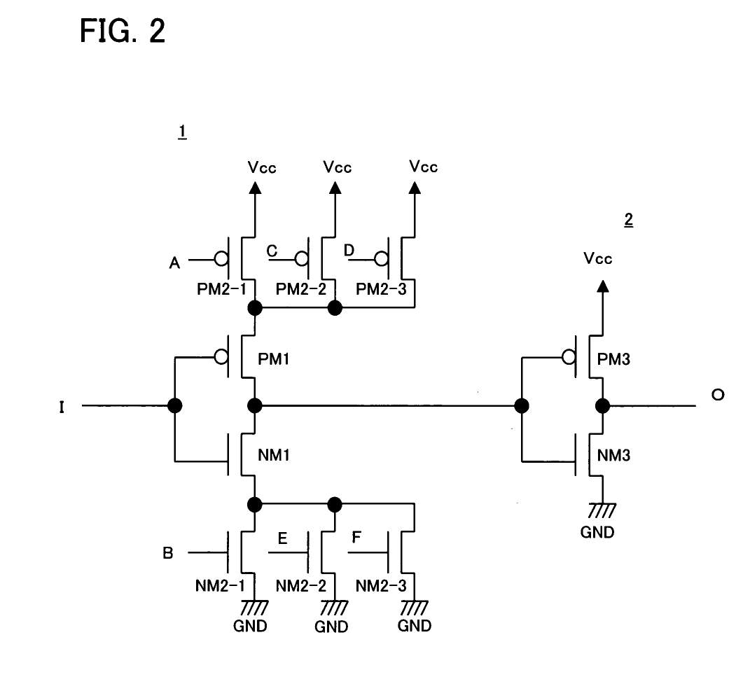

FIG. 2 is a diagram showing the configuration of the delay adjustment circuit 102 of FIG. 1. Referring to FIG. 2, P-channel MOS transistors PM2-1, PM2-2 and PM2-3 which have gates supplied with control signals A, C and D, respectively, have sources connected in common to a power supply Vcc, and have drains connected in common to the source of the P-channel MOS transistor PM1. The P-channel MOS transistors PM2-1 to PM2-3 constitute a first variable resistance unit (voltage-controlled variable resistance unit). On the other hand, N-channel MOS transistors NM2-1, NM2-2 and NM2-3, which have gates supplied with control signals B, E and F, respectively, have sources connected in common to the ground GND, and have drains connected in common to the source of the N-channel MOS transistor NM1. The N-channel MOS transistors NM2-1 to NM2-3 constitute a second variable resistance unit (voltage-controlled variable resistance unit). A P-channel MOS transistor PM1 and an N-channel MOS transistor NM1 have gates connected in common to the input terminal I, and have drains connected in common to constitute an output end. Thus, the above-described configuration performs the role of an inverter (an inverting buffer circuit) for inverting an input signal to output the resulting inverted signal, and is connected to an input end of a CMOS inverter 2. The CMOS inverter 2 is made up by a P-channel MOS transistor PM3 and an N-channel MOS transistor NM3 which have sources connected a power supply Vcc and to the ground GND, respectively, have drains connected in common to an output terminal O, and having gates connected in common to constitute an input end of the CMOS inverter 2.

To the gates of the P-channel MOS transistors PM2-1, PM2-2 and PM2-3 are supplied control signals A, C and D, respectively, so that at least one of those P-channel MOS transistors is in a conducting state. To the gates of the N-channel MOS transistors NM2-1, NM2-2 and NM2-3 are also supplied control signals B, E and F, respectively, so that at least one of those N-channel MOS transistors is in a conducting state.

The number of parallel connected P-channel MOS transistors PM2-1, PM2-2 and PM2-3 and that of parallel connected N-channel MOS transistors NM2-1, NM2-2 and NM2-3 may, of course, be other than three and may be any optionally selected number. It is also possible to halt the test mode (to halt the adjustment of the delay amount) on production line in order to fix the resistance of the variable resistance unit to an optimum value.

The operation of the circuit of FIG. 2 will now be described. The value of the total channel width W of the inverter 1 is rendered variable based on the combination of the potential levels of the signals A to F for supplying respective gate potentials of the P-channel MOS transistors PM2-1, PM2-2 and PM2-3 and the N-channel MOS transistors NM2-1, NM2-2 and NM2-3, in e.g. a test mode.

The potentials of the signals A to F are controlled so that at least one of the P-channel MOS transistors PM2-1, PM2-2 and PM2-3 is in an on state and so that at least one of the N-channel MOS transistors NM2-1, NM2-2 and NM2-3 is in an on state.

When the input signal I goes from LOW to HIGH, the PMOS transistor PM1 is turned off, while the NMOS transistor NM1 is turned on, so that the output of the inverter 1 goes LOW. Accordingly, the output terminal O of the inverter 2 goes from LOW to HIGH. When the input signal I goes from HIGH to LOW, the PMOS transistor PM1 is turned on, while the NMOS transistor NM1 is turned off, so that the output of the inverter 1 goes HIGH. Accordingly, the output terminal O of the inverter 2 goes from HIGH to LOW.

With the present embodiment, the total W value of the inverter 1 may be increased or decreased to adjust the driving capability of the inverter 1 by adjusting the variable resistance based on signals A to F supplying the respective gate potentials of the P-channel MOS transistors PM2-1, PM2-2 and PM2-3 and the N-channel MOS transistors NM2-1, NM2-2 and NM2-3. Thus, the setup time and the hold time of the latch circuit 103 may be adjusted with an adjustment width on the order of tens of picoseconds (ps).

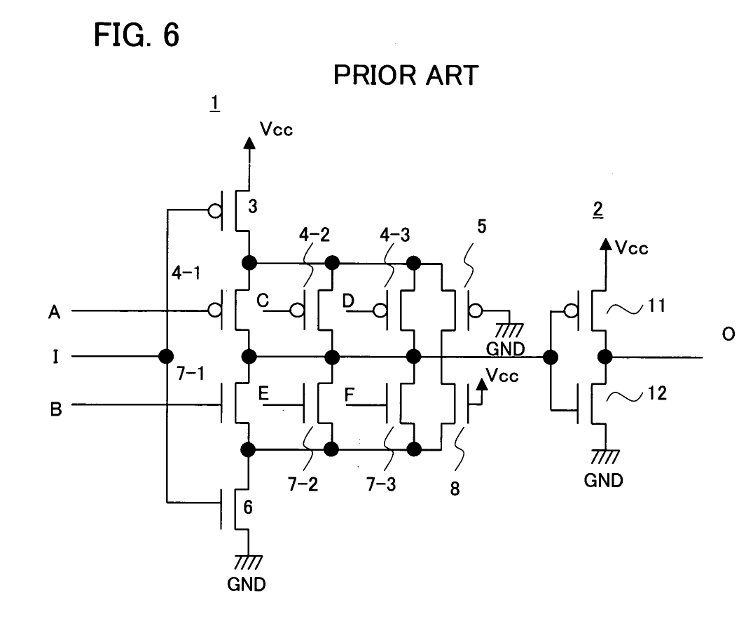

With the present embodiment, shown in FIG. 2, as compared to the configuration of the comparative example of FIG. 6, the propagation delay time (tPD) from an input to an output of the delay adjustment circuit may be reduced to enable a high frequency operation.

Moreover, with the present embodiment, in which a variable resistor unit is provided between a first power supply or a second power supply and the transistors to which is coupled the input signal I, the propagation delay time as from transition of the input signal I until transition of the output of the inverter I may be shorter than the propagation delay time of the comparative example shown in FIG. 6.

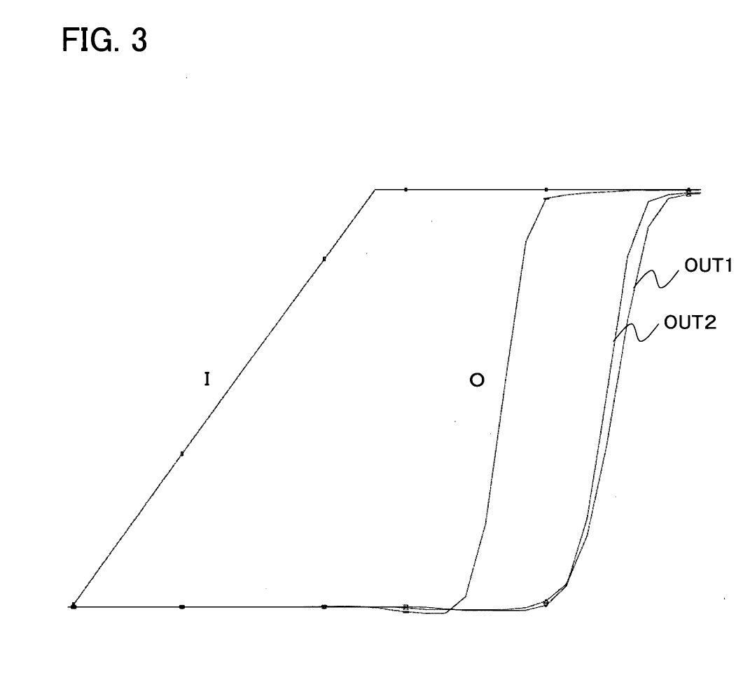

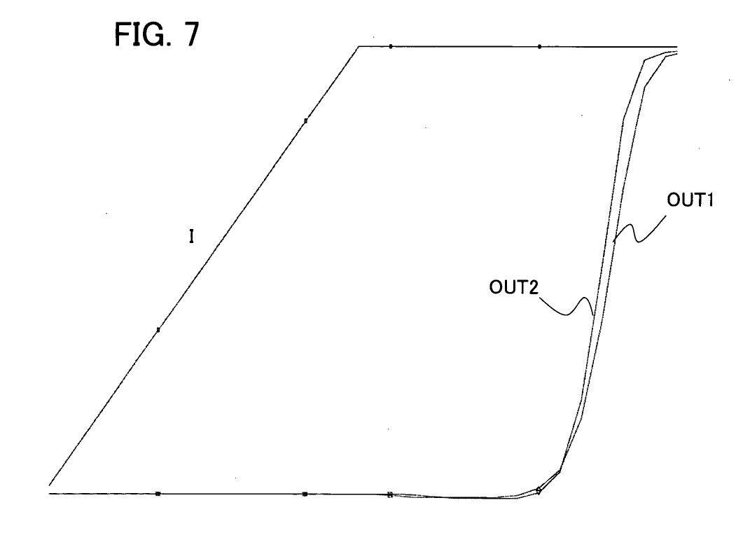

FIG. 3 shows the results of circuit simulation of the delay adjustment circuit of the present embodiment shown in FIG. 2, together with the results of circuit simulation of the comparative example. In FIG. 3, I denotes an input signal waveform, which is supplied as input to the delay adjustment circuit, and is a signal voltage waveform for the input signal I shown in FIG. 2. In FIG. 3, showing the results of the comparative example, a signal voltage waveform of FIG. 6 is also indicated as I. An output signal waveform O of FIG. 3 is a signal voltage waveform at the output O of FIG. 2. In FIG. 3, OUT1 and OUT2 correspond to the output signal voltage waveforms OUT1 and OUT2 of the results of simulation shown in FIG. 7.

As may be apparent from the comparison of O, OUT1 and OUT2 of FIG. 3, the propagation delay time tPD of the output signal waveform O of the present embodiment, herein the delay time from the rise of I to the rise of O, has become shorter than the corresponding time of the configuration of FIG. 6, so that the present embodiment provides for operations at higher frequencies.

Although the present invention has so far been described with reference to the preferred embodiments, the present invention is not limited to the particular configurations of these embodiments. It will be appreciated that the present invention may encompass various changes or corrections such as may readily be arrived at by those skilled in the art within the scope and the principle of the invention.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A delay adjustment circuit receiving an input signal at an input terminal thereof and adjusting the amount of delay of the input signal to output the signal adjusted for delay at an output terminal thereof, said delay adjustment circuit comprising:
a buffer circuit having an input end connected to said input terminal;
a first variable resistance unit including one or a plurality of variable resistance devices, said first variable resistance unit being provided on a power supply path between said buffer circuit and a high potential power supply; and
a second variable resistance unit including one or a plurality of variable resistance devices, said second variable resistance unit being provided on a power supply path between said buffer circuit and a low potential power supply;
wherein each resistance value of said variable resistance devices is varied by an associated control signal received to adjust said amount of delay.

2. The delay adjustment circuit according to claim 1, wherein, in measuring setup time and hold time of a latch circuit which is arranged on a succeeding stage of said delay adjustment circuit and receives an output signal of said delay adjustment circuit as input, fine adjustment of the amount of delay is performed by said control signal.

3. The delay adjustment circuit according to claim 1, wherein
said first variable resistance unit includes, as the variable resistance devices, a first set of transistors arranged in parallel between a high potential side of said buffer circuit and said high potential power supply and having control terminals supplied with control signals, respectively; and
said second variable resistance unit includes, as the variable resistance devices, a second set of transistors arranged in parallel between a low potential side of said buffer circuit and said low potential power supply and having respective control terminals supplied with control signals, respectively;
at least one of the first set of transistors being set in an on-state and at least one of the second set of transistors being set in an on-state.

4. The delay adjustment circuit according to claim 1, wherein said buffer circuit comprises a first inverter; said delay adjustment circuit further comprising a second inverter having an input end connected to an output end of said first inverter and having an output end connected to said output terminal.

5. A delay adjustment circuit receiving an input signal at an input terminal thereof and adjusting the amount of delay of the input signal to output the signal adjusted for delay at an output terminal thereof, said delay adjustment circuit comprising:
a first inverter circuit having an input end connected to said input terminal and an output end for outputting a signal obtained on inverting said input signal;
a first set of transistors arranged in parallel between a high potential side of said first inverter and a high potential power supply and having control terminals supplied with control signals, respectively; and
a second set of transistors arranged in parallel between a low potential side of said first inverter and a low potential power supply and having control terminals supplied with control signals, respectively;
at least one of the first set of transistors being set in an on-state and at least one of the second set of transistors being set in an on-state.

6. The delay adjustment circuit according to claim 5, further comprising:
a second inverter circuit having an input end connected to an output end of said first inverter circuit and having an output end connected to said output terminal.

7. The delay adjustment circuit according to claim 5, wherein said first inverter comprises a CMOS inverter including a P-channel MOS transistor and an N-channel MOS transistor having gates connected in common to form an input end and having drains connected in common to form an output end;
said first set of transistors comprising a plurality of P-channel MOS transistors which have sources connected in common to said high potential power supply, have drains connected in common to the source of P-channel MOS transistor of said CMOS inverter and have gates supplied with said control signals, respectively;
said second set of transistors comprising a plurality of N-channel MOS transistors which have sources connected in common to said low potential power supply, have drains connected in common to the sources of N-channel MOS transistors of said CMOS inverter and have gates supplied with said other control signals.

8. A synchronous semiconductor device comprising:
a latch circuit for receiving an output signal of said delay adjustment circuit as set fourth in claim 1 and for sampling said output signal responsive to an input clock signal for sampling.
